(19) United States
(12) Patent Application Publication
(10) Pub. No.: US 2016/0260602 A1
(43) Pub. Date: Sep. 8, 2016

(54) ADHESION IMPROVEMENTS FOR OXIDE-SILICON STACK

(71) Applicant: APPLIED MATERIALS, INC., Santa Clara, CA (US)

(72) Inventors: Subbalakshmi SREEKALA, Milpitas, CA (US); Nagarajan RAJAGOPALAN, Santa Clara, CA (US); Bok Hoen KIM, San Jose, CA (US)

(21) Appl. No.: 14/400,735

(22) PCT Filed: Oct. 15, 2014
(86) PCT No.: PCT/US2014/060647

§ 371 Date: Nov. 12, 2014

Related U.S. Application Data
(60) Provisional application No. 61/899,735, filed on Nov. 4, 2013.

(51) Int. Cl. H01L 21/02; H01L 21/324

(52) U.S. Cl. CPC H01L 21/02274; H01L 21/02164; H01L 21/02301; H01L 21/02532; H01L 21/02592; H01L 21/0262; H01L 21/02661; H01L 21/324

(57) ABSTRACT

Embodiments generally relate to methods of controlling hydrogen content in a silicon oxide/amorphous silicon stack. By precleaning the substrate of residues, controlling the delivery of hydrogen during the stack deposition and preventing outgassing of hydrogen from deposited layers during subsequent layer deposition and processing, the effects of delamination can be avoided in the formation of devices, such as 3D NAND devices.

### BACKGROUND

1. Field

Embodiments described herein generally relate to methods of improving stack adhesion within computer memory devices.

2. Description of the Related Art

Computer memory devices continue to move toward smaller geometries with increased capacity at less cost. To this end, components of memory cells are stacked on top of each other to create 3D cells. One such technology is NAND flash memory, which may be found in memory cards, USB flash drives, solid-state drives and similar products, for data storage and transfer. In NAND flash memory, memory cells made from transistors are connected in series, and can be stacked into vertical layers to create densely packed, high capacity devices. With no moving parts, flash drives use less power and are more durable than ordinary hard drives. Accordingly, there is great interest in increasing the capacity of flash drives, while reducing their size and cost.

However, as flash technology has progressed, limitations exist in how to create high capacity devices on a small scale. For example, different materials that are combined on a microscopic scale have different physical properties that lead to non-uniformities in a flash memory device. Further, high heat process steps, including certain process steps at temperature from 550° C. to 800° C., can cause the different materials to undergo volume changes at different rates. In one example, oxide/Si stacks can blister, peel, bubble or otherwise delaminate at high temperatures. The cause of the delamination is believed to be related to either improper cleaning of the wafer prior to the oxide/Si stack deposition or hydrogen outgassing from the oxide/Si stack. These delamination issues can cause a deposited stack of different layers to warp. Warping problems limit the number of layers that can be effectively deposited in manufacturing, and it can reduce the number of functioning memory strings available to the overall memory device.

Therefore, there is a need for improved methods of forming memory structures, such as 3D memory structures. Further, there is a need for improved methods of preventing the failure of oxide/Si layers.

### SUMMARY

Embodiments disclosed herein generally relate to methods of improving adhesion of a silicon oxide/silicon stack. In one embodiment, a method can include positioning a substrate in a PECVD chamber; energizing a preclean gas into a plasma to create an energized preclean gas; delivering the energized preclean gas to the substrate; purging the PECVD chamber; and depositing one or more silicon oxide/silicon containing stacks on a substrate in the presence of a vacuum. Depositing a silicon oxide/silicon-containing stack can include energizing a first process gas into a first plasma; depositing a first material layer on the substrate from the first plasma; energizing a second process gas into a second plasma; depositing a layer of a second material on the substrate from the second plasma; repeating the above steps until a predetermined number of the first material layers and the second material layers have been deposited on the substrate, wherein the first material layer and the second material layer are either a silicon oxide layer or an amorphous silicon layer and wherein the second material layer is different from the first material layer.

In another embodiment, a method of forming a stack can include energizing a first process gas into a first plasma; depositing a first material layer on a substrate from the first plasma, the layer of the first material having a first thickness; plasma purging the PECVD chamber to expose a surface of the first material layer, creating first gas contaminants; gas purging the PECVD chamber to remove the first gas contaminants; energizing a second process gas into a second plasma; depositing a second material layer on the first material layer from the second plasma, the second material layer having a second thickness; plasma purging the PECVD chamber to expose a surface of the second material layer, creating second gas contaminants; gas purging the PECVD chamber to remove the second gas contaminants; and repeating the above steps until a predetermined number of the first material layers and the second material layers have been deposited on the substrate, wherein, during at least one of the above steps, at least a portion of the chamber, the substrate support or combinations thereof is maintained at a temperature of between about 500 degrees Celsius and about 650 degrees Celsius, wherein the first material layer and the second material layer are either a silicon oxide layer or an amorphous silicon layer and wherein the second material layer is different from the first material layer.

### BRIEF DESCRIPTION OF THE DRAWINGS

So that the manner in which the above recited features of the methods, devices and apparatus can be understood in detail, a more particular description, briefly summarized above, may be had by reference to embodiments, some of which are illustrated in the appended drawings. It is to be noted, however, that the appended drawings illustrate only typical embodiments and are therefore not to be considered limiting of its scope, for the methods, devices and apparatus described herein may admit to other equally effective embodiments.

FIG. 1 depicts a device according to one embodiment described herein;

FIG. 2 depicts a PECVD processing chamber according to one embodiment disclosed herein;

FIG. 3 depicts a flow diagram of a method for plasma treatment of the substrate prior to forming a stack, according to one embodiment described herein; and

FIGS. 4A and 4B depicts a flow diagram of a method for controlling hydrogen in the silicon oxide/silicon stack according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments generally relate to methods of preventing the failure of silicon oxide/silicon stacks in alternating layer deposition, such as in 3D NAND applications. Embodiments disclosed herein may be practiced in PECVD chambers or RTP chambers available from Applied Materials, Inc., of Santa Clara, Calif. It is contemplated that other chambers, including those produced by other manufacturers, may benefit from embodiments described herein.

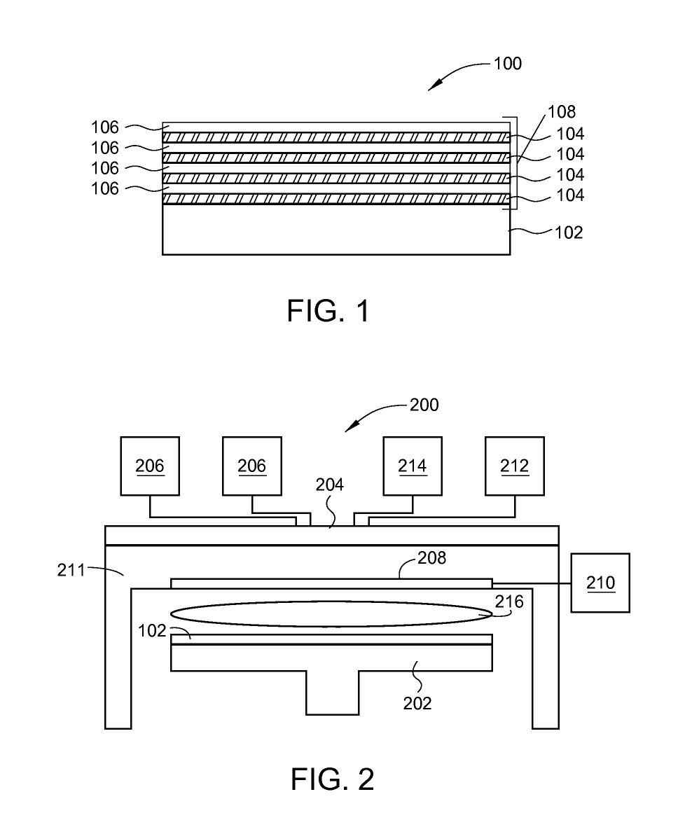

FIG. 1 depicts a device 100 according to one embodiment described herein. The device 100 includes a substrate 102 with a plurality of first material layers 104 and a plurality of second material layers 106. The subsequent layers can repeat this alternating pattern of first material layers 104 and second material layers 106. In one embodiment, the first material layer 104 can be a silicon oxide layer and the second material layer 106 can be an amorphous silicon layer. In further embodiments, the first material layer/second material layer stacks can be oxide/silicon, silicon/doped silicon, or silicon/nitride. All of these combinations of materials can be used in Bit-Cost Scalable (BiCS), Terabit Cell Array Transistor (TCAT) and other 3D memory structures. In other embodiments, the first material layer/second material layer stacks can be other combinations of materials. The deposition order of the first material layers 104 and second material layers 106 on the substrate 102 can also be reversed.

The number of layers can depend upon the memory device being fabricated. In one embodiment, the stack numbers could be 8×, or 16×, or 24×, or even higher, where each stack of 8, 16, 24, 32, 64, 128 or more layers corresponds to one memory device. The two layers of different materials form each stack, so the corresponding number of layers for an 8× stack number can be 16, a 16× stack number can have 32 layers, a 24× stack number can have 48 layer, and a higher stack number can have a respectively higher number of layers.

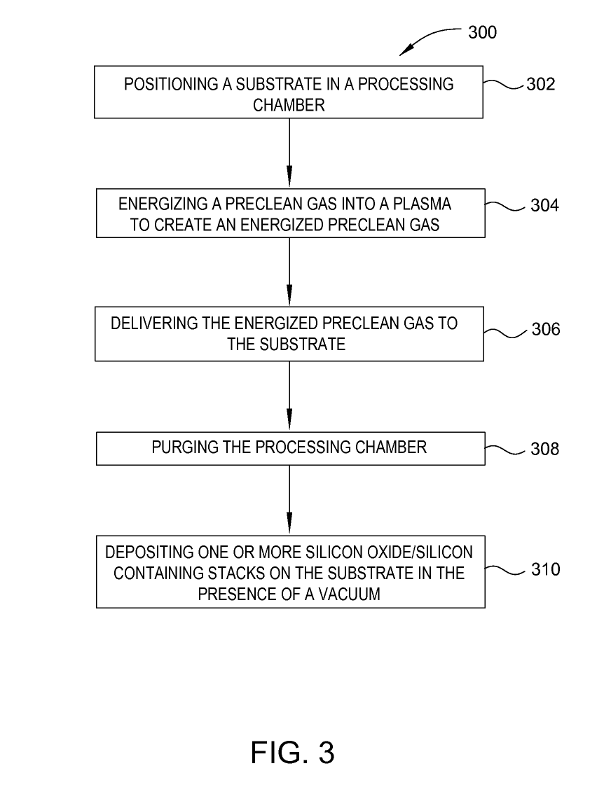

FIG. 2 depicts a PECVD processing chamber 200 according to one embodiment disclosed herein. The processing chamber 200 includes a pedestal 202, a process gas manifold 204, a process gas source 206, an electrode 208, RF power source 210 emitting an alternating current RF electrical power, a heater 211 and a purge gas source 212. In an embodiment, the electrode 208 can be directly over the pedestal 202 which is electrically grounded in a capacitively coupled configuration. In an embodiment, the electrode 208 can be a showerhead structure that has flow paths for the process gases. The process and purge gases can flow through the manifold 204 and the electrode 208 into the processing chamber 200 above the pedestal.

During processing, the substrate 102 is placed on the pedestal 202 and vacuum is applied to the PECVD processing chamber 200. Energy can be applied to the heater 211 to heat the substrate 102. A first group of processing gases passes through the manifold 204 into the processing chamber 200. The electrode 208 is energized by the RF power source 210 creating an electrical field between the electrode 208 and the grounded pedestal 202. In an embodiment, the pedestal 202 can be on a variable height adjuster that allows the spacing between the top of the substrate 102 and the electrode 208 to be controlled. The first group of process gases is energized by the RF electrical field and generates a plasma 216. The plasma 216 has a significant percentage of the atoms or molecules that are ionized and the atoms or molecules release electrons. These energetic electrons can induce dissociation of precursor molecules and the creation of large quantities of free radicals. This results in the deposition of material on the substrate 102. The deposition can stop once the desired thickness of the first material is deposited. The layer thickness of the first material can be between 100 Å to 1000 Å.

After the first material is deposited on the substrate 102, the PECVD processing chamber 200 is plasma purged. A purge gas can flow from a purge gas source 212 into the manifold 204 and the processing chamber 200. The electrode 208 and pedestal 202 are energized generating a purge gas plasma. Purge gases which can be used in the processing chamber 200 including NH₃, N₂, N₂O, H₃, Ar and other suitable plasma purge gases. During the purge process, the heat and pressure can be maintained in the processing chamber. The plasma purge conditions the surface of the exposed layer for additional depositions. The conditioned surface results in a smooth interface between layers and better adhesion between layers, as well as better particle control. In some embodiments, a rougher interface may be desirable for better layer bonding and a different or additional plasma purge process may be performed. After the plasma purge is completed, the energy to the electrode 208 and pedestal 202 can be turned off and a gas purge from a gas purge source 214 flows into the manifold 204 and the processing chamber 200 to remove all gas contaminants. In an embodiment, one or more components of the precursor gas are stopped during the purge process. For example, if the process gas includes a mixture of SiH₄ and N₂O, the purge gas can only include N₂O and the flow of SiH₄ is shut off. In other embodiments, a different purge gas or purge gases can be used.

After the plasma and gas purges are complete, the second material can be deposited on the substrate. The electrode 208 is energized by the RF power source 210 creating an electrical field between the electrode 208 and a second group of process gases are energized by the electrical field generating a plasma 216. The deposition can stop once the desired thickness of the second material is deposited. The layer thickness of the second material can be between 100 Å to 1000 Å. After the second material layer is deposited, the processing chamber 200 can be plasma purged as described above. The energy to the electrode 208 can then be removed and the processing chamber 200 is gas purged as described above. Once the plasma and gas purges are complete, the process of depositing the first material and the second material can be repeated until the required layers have been deposited. The substrate 102 can then be removed from the processing chamber 200 for additional processing.

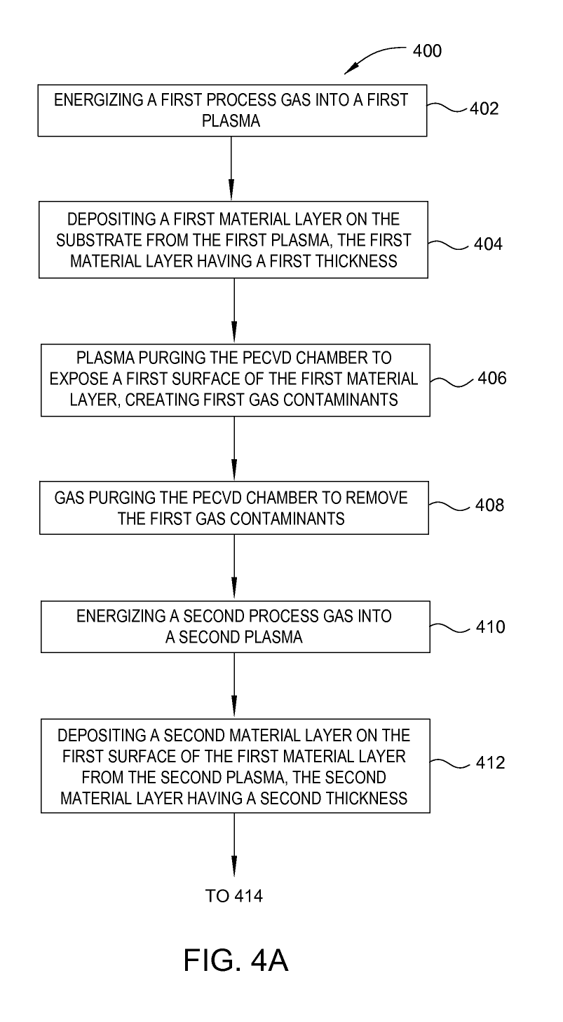

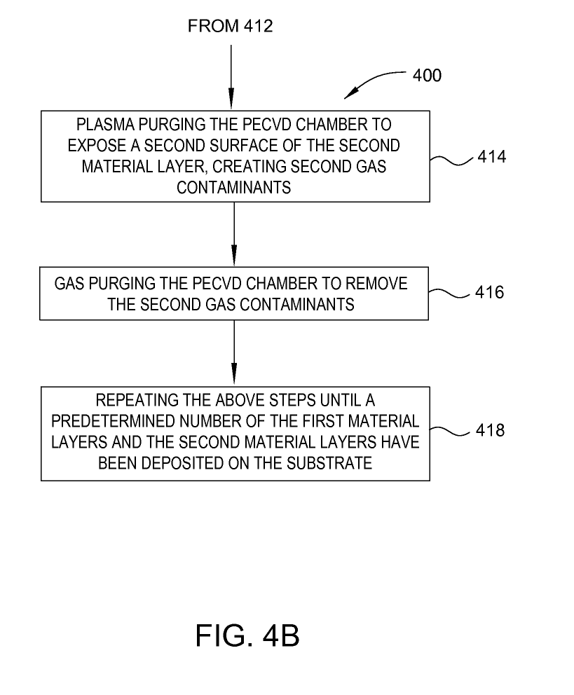

During the deposition of the silicon oxide/silicon stacks deformations can occur due to a number of factors, such as preexisting defects in the substrate, excess hydrogen in the substrate, excess hydrogen in the stack, defects in the stack to stack interface or other issues. FIGS. 3 and 4A-4B describe methods for resolving some of the above described issues.

FIG. 3 depicts a flow diagram of a method 300 for plasma treatment of the substrate prior to forming a stack, according to one embodiment described herein. In one or more embodiments, a substrate will have carbon-containing residues, oxygen-containing residues or other residues on one or more of the exposed surfaces. Though substrate cleaning steps, such as pre-deposition etch steps, can remove some of the residues, other residues can remain. These remaining residues can then interfere with stack deposition. One or more of the above residues can be removed using an activated oxygen-containing gas, an activated hydrogen containing gas or an activated inert gas.

The method 300 begins with positioning a substrate in a processing chamber, as in element 302. In one embodiment, the processing chamber is a PECVD chamber as described above with reference to FIG. 1. The substrate can be a silicon substrate or others substrates. The vacuum pressure in the chamber can be between about 0.5 Torr-10 Torr. The processing chamber is heated to between about 180° C.-650° C. The temperature and pressure can be maintained throughout the subsequent process steps or the temperature may vary between steps.

With the substrate positioned in the processing chamber, a preclean gas is energized into a plasma to create an energized preclean gas, as in element 304. The preclean gas can be an oxygen-containing gas, such as such as O₂, O₃, N₂O, NO, NO₂, N₂O₃ or combinations thereof. The oxygen-containing gas can further contain hydrogen, however this is not necessary. The oxygen-containing gas will dissociate and react with carbon and other impurities. The resulting products are largely gaseous such as CO₂ and water vapor, which is then removed from the chamber. In another embodiment, the preclean gas can be a hydrogen-containing gas, such as NH₃ or H₂ or combinations thereof. The hydrogen will dissociate and react with oxides to form water. In another embodiment, the preclean gas can be an inert gas, such as argon. The inert gas will sputter off the surface residues, including oxides, carbon containing residues and others. The sputtering is a low energy sputter, using a low pressure and a low energy plasma. In this way, the energized inert gas only sputters the weakly bonded portions of the surface of the substrate. Any of the preclean gases described above can be further mixed with an inert gas or a second inert gas. Inert gases include nitrogen, argon, helium, other noble gases or other non-reactive gases.

The energized preclean gas can be either converted to a plasma directly or flowed into a plasma formed from another gas. In one example, a plasma is formed from an inert gas. The preclean gas is then delivered to the plasma to create the energized preclean gas. Further, the plasma can be formed in the processing region of the processing chamber or the plasma can be formed remotely and delivered to the processing region of the processing chamber.

In the processing chamber described above, the plasma is formed in the processing region. The plasma can be an RF plasma or other types of plasma. The RF power applied to the electrode can between about 45 watts (W) and about 1000 W. The spacing between the substrate and the electrode can be between about 200 mils and about 800 mils. The preclean gas can have a flow rate of about 1000 standard cubic centimeters per minute (sccm) to about 20,000 sccm for a 300 mm substrate. In another embodiment, the flow rate of the preclean gas per square millimeter of surface area of the substrate can be from about 0.011 sccm/mm² to about 0.22 sccm/mm².

After the preclean gas has been energized, the preclean gas is then delivered to the substrate, as in element 306. The energized preclean gas can then react with oxides formed on the surface of the substrate, carbon-containing residues from previous processes or other loosely bonded residues.

The detached or reacted residues are then purged from the processing chamber, as in element 308. As described above, the energized preclean gas can react with surface residues to form water vapor, CO2, or other oxides or hydrides. The molecules are largely gaseous and thus can be purged from the chamber. The purge step includes a purge gas, such as an inert gas. The purge gas is delivered at a flow rate of from about 2,000 sccm to about 30,000 sccm for a 300 mm substrate. In another embodiment, the flow rate of the preclean gas per square millimeter of surface area of the substrate can be from about 0.022 sccm/mm² to about 0.33 sccm/mm². The purge gas process results in better particle control and prevention of redeposition of the removed residues.

Once the processing chamber is purged, one or more silicon oxide/silicon stacks can be deposited on the substrate, as in element 310. In one embodiment, the stacks are deposited in the presence of a vacuum. For the stack deposition, the substrate is maintained in a processing chamber and a vacuum is applied to the chamber. The vacuum pressure in the chamber can be between about 0.5 Torr and about 10 Torr. The processing chamber is heated to between about 180° C. and about 650° C. A high frequency or RF power can then be applied to the electrode at between about 45 W and about 1000 W. The spacing between the substrate and the electrode can be between about 200 mils and about 800 mils. The first process gases includes a silicon containing gas and an oxygen containing gas. In this embodiment, the silicon-containing gas is silane (SiH₄) and the oxygen containing gas is N₂O. The SiH₄ can have a flow rate of about 20 sccm to about 1000 sccm and the flow rate of N₂O can be from about 1000 sccm to about 20000 sccm for a 300 mm substrate. In another embodiment, the flow rate of the SiH₄ per square millimeter of surface area of the substrate can be from about 0.00022 sccm/mm² to about 0.011 sccm/mm² and the flow rate of the N₂O per square millimeter of surface area of the substrate can be from about 0.11 sccm/mm² to about 0.22 sccm/mm². The SiH₄ and N₂O will be energized and converted into a plasma that contains Si and O ions. The reaction of the ions causes a layer of silicon oxide to be deposited on the substrate. The deposition is stopped after the required thickness of silicon oxide is deposited.

After the silicon oxide layer is deposited, the silicon layer can be deposited over the silicon oxide layer. The pressure in the chamber can be between about 0.5 Torr and about 10 Torr. The processing chamber can be heated to between about 400° C. and about 650° C. The high frequency or RF power applied to the electrode can between about 50 W and about 700 W and the spacing between the substrate and the electrode can be between about 200 mils and about 800 mils. The process gases can include a silicon-containing gas and an inert gas. In this embodiment, the process gases includes SiH₄ and He. The SiH₄ can have a flow rate of about 50 sccm to about 2000 sccm and the flow rate of He can be about 1000 sccm to about 20000 sccm for a 300 mm substrate. In another embodiment, the flow rate of the SiH₄ per square millimeter of surface area of the substrate can be from about 0.00056 sccm/mm² to about 0.022 sccm/mm² and the flow rate of the He per square millimeter of surface area of the substrate can be from about 0.011 sccm/mm² to about 0.22 sccm/mm². The process gases are energized to form silicon ions that react with electrons to deposit a layer of the desired number of stacks have been deposited. The process steps can then be repeated until the required number of silicon oxide and amorphous silicon layers have been deposited on the substrate.

After the stacks have been deposited, the processing chamber is brought to ambient pressure and the substrate is removed. For 3D memory at least eight layers of material should be deposited on the substrate. Additional processing can be performed in other processing chambers.

In another embodiment, the substrate can be exposed to a silane soak prior to the deposition of the first material layers and the second material layers. SiH₄ can be delivered to the processing region of the processing chamber. The SiH₄ can have a flow rate of about 50 sccm to about 2000 sccm for a 300 mm substrate. In another embodiment, the flow rate of the SiH₄ per square millimeter of surface area of the substrate can be from about 0.00056 sccm/mm² to about 0.022 sccm/mm².

FIGS. 4A and 4B depicts a flow diagram of a method 400 for controlling hydrogen in the silicon oxide/silicon stack according to one embodiment. Hydrogen outgassing from the silicon oxide/silicon stack can lead to separation of or bubbling in the underlying layers of the stack. As such, the stack can become distorted over time. By removing excess hydrogen from the stack, the planarity of the stack can be maintained over more deposition cycles.

The method 400 begins by energizing a first process gas into a first plasma, as in element 402. The first process gas can be the same as the first process gas described with reference to FIG. 3. The first process gas can be delivered to the chamber and activated into a plasma using the parameters described above with reference to FIG. 3.

Using the first plasma, a first material layer is deposited onto the substrate, as in element 404. The first material layer has a first thickness. The deposition of the first material layer can be the same as described above with reference to FIG. 3. The first thickness can be used to control the overall tensile or compressive stress of the stack. The first thickness can be between 100 Å and about 1000 Å.

Once the first material layer is deposited, the PECVD chamber can be plasma purged to expose a first surface of the first material layer, as in element 406. After the silicon oxide is deposited, the PECVD processing chamber can be plasma purged and gas purged. The temperature can be between about 180° C. and about 650° C. and the vacuum pressure can be between about 0.5 Torr and about 10 Torr. The spacing can be between the substrate and the electrode can be between about 200 mils to about 800 mils. A purge gas of N₂O can be delivered to the processing region of the processing chamber at a flow rate of about 2000 sccm to about 3000 sccm. In another embodiment, the flow rate of the purge gas per square millimeter of surface area of the substrate can be from about 0.022 sccm/mm² to about 0.33 sccm/mm². The electrode and pedestal are energized to generate a purge gas plasma with power between 100 W and 1000 W.

Then, the PECVD chamber can be gas purged to remove the first gas contaminants, as in element 408. A purge gas of N₂O can be further delivered to the processing region of the processing chamber at a flow rate of about 2000 sccm to about 3000 sccm without the formation of a plasma. In another embodiment, the flow rate of the purge gas per square millimeter of surface area of the substrate can be from about 0.022 sccm/mm² to about 0.33 sccm/mm². The plasma purging and N₂O purging cleans the processing chamber and results in a smooth interface between layers, better adhesion between the deposited layers and better particle control. The exposure of the first surface can create first gas contaminants.

Once the PECVD chamber is purged, a second plasma gas can be energized into a second plasma, as in element 410. The second process gas can be the same as the second process gas described with reference to FIG. 3. The second process gas can be delivered to the chamber and activated into a plasma using the parameters described above with reference to FIG. 3.

Using the second plasma, a second material layer can be deposited on the first surface of the first material layer, as in element 412. The second material layer has a second thickness. The second material layer can be deposited as described with reference to FIG. 3. In one embodiment, boron can be added to the second material layer. Boron decreases the poly hydrides formed during the deposition step to mono hydrides, effectively decreasing the dangling bonds. By decreasing the dangling bonds, the surface of the second material layer, such as an amorphous silicon layer, can be made more adherent to the subsequently deposited first material layer, such as a silicon oxide layer.

After the second material layer is deposited, the PECVD chamber can be plasma purged to expose a second surface of the second material layer, as in element 414. The purge process can be the same process described above with reference to element 406 using an N₂ purge gas at a flow rate of about 2,000 sccm to about 3000 sccm. In another embodiment, the flow rate of the SiH₄ per square millimeter of surface area of the substrate can be from about 0.00056 sccm/mm² to about 0.022 sccm/mm². As with the first surface, the exposure of the second surface can create second gas contaminants.

Then, the PECVD chamber can be gas purged to remove the second gas contaminants, as in element 416. The purge process can be the same process described above with reference to element 408 using an N₂ purge gas at a flow rate of about 2,000 sccm to about 3000 sccm. In another embodiment, the flow rate of the SiH₄ per square millimeter of surface area of the substrate can be from about 0.00056 sccm/mm² to about 0.022 sccm/mm².

The steps described in elements 402-416 can then be repeated until a predetermined number of the first material layers and the second material layers have been deposited on the substrate, as in element 418.

At one or more of the elements 402-418 above, the temperature of the substrate can be maintained above about 500 degrees Celsius. In one embodiment, the temperature is maintained between about 500 degrees Celsius and about 650 degrees Celsius. The increased temperature will cause hydrogen to be released from the deposited layers. Therefore, subsequently deposited layers won't bubble or otherwise delaminate when processed at higher temperatures. The heating can be performed in an rapid thermal processing (RTP) chamber, wherein the substrate with one or more deposited first material layers and/or deposited second material layers is transferred to the RTP chamber and annealed at a temperature below 650 degrees Celsius. The amorphous nature of the layer will be maintained at temperatures below 650 degrees Celsius. The anneal process can be performed for about 3 to about 10 minutes, such as about 7 minutes. In another embodiment, the ramp rate is controlled during the pre-anneal. By controlling the ramp rate, the hydrogen outgassing from the deposited layers and/or the substrate can be controlled.

At one or more of the elements 402-418 above, the substrate can have a plurality of temperature zones. In one embodiment, the temperature zones can be an inner zone of the substrate and an outer zone which circumscribes the inner zone. The outer zone and the inner zone can be circular. The temperature in the outer zone can be within about 5 to about 20 degrees Celsius of the inner zone. The adhesion issues happen more frequent at edge of the wafer. By using a dual zone heater, and increasing outer zone temperature as compared to the inner zone, the hydrogen content can be reduced around edge.

In another embodiment, the hydrogen content of the layers can decreased by reducing the excess or unreacted hydrogen in the deposition gas. The received hydrogen content can be reduced by increasing pressure, lowering the power for plasma formation, increasing the SiH₄ flow, and increasing the spacing between the substrate and the electrode.

In another embodiment, hydrogen content can be reduced by increasing the thickness of the first material layer as compared to the by second material layer. This can be achieved by either increasing the thickness of the first material layer or decreasing the thickness of the second material layer.

Another problem that can occur is that the deposition of different materials can induce compression or tension stress after being deposited on the substrate. This stress can result in bending of the substrate. In one example, a layer of a first material is deposited on the substrate. The first material can then expand causing compressive stress. The compressive stress of the first material layer is opposed by the substrate which causes the edges of the substrate to bow down.

In another example, a layer of a second material can be deposited on the substrate and the second material may induce a tensile stress. The tensile stress will also be opposed by the substrate which results in the edges of the substrate bending upward. Because the fabrication tolerances must be very accurate, any bending of the substrate or bumps in the substrate can result in alignment issues when a subsequent lithography processing is performed. This misalignment can result in fabrication errors and defective device construction.

In order to correct this problem, in an embodiment it is possible to tune the stress applied to the substrate by each deposited layer. The stress can be determined by the material being deposited. The stress can also be tuned within a limited range by adjusting the deposition processing conditions including process temperature, flow rates of the precursor gases, gas pressure and plasma density. For example, a cooler processing temperature can produce compressive stress and a hotter processing temperature can produce tensile stress. A lower plasma pressure can increase ion bombardment to the reaction species, and thus result a compressive stress, and conversely a higher plasma pressure can result in tensile stress. A plasma density can be increased by increasing RF power or decreasing the spacing above the substrate which can produce more ion bombardment to the reaction species can result in a compressive stress and a lower plasma density can result in tensile stress. By controlling the temperature and plasma density, the stress of the deposited materials can be predicted.

In one embodiment, the stress of the first material layer or the silicon oxide layer can be changed to a tensile regime. As described above, the stress of the first material layer can be changed to the tensile regime by lowering the plasma density. The plasma density can be lowered by lowering the power, increasing the pressure, increasing the flow of the deposition gases, creating a wider spacing between the substrate and the electrode or by combinations thereof. If oxide layer is tensile and is not dense enough, hydrogen can outgas easier out of the films during subsequent high temperature process steps.

Benefits of the methods described herein include prevent deposition errors and preventing stack damage due to outgassing during deposition. The methods described herein can be used to prevent delamination issues that can arise during processing, which will allow for larger and more complex stacks to be deposited while reducing device failure.

While the foregoing is directed to embodiments of the present methods, devices and apparatus, other and further embodiments may be devised without departing from the basic scope thereof, and the scope thereof is determined by the claims that follow.

1. A method comprising:
positioning a substrate in a processing chamber;
energizing a preclean gas into a plasma to create an energized preclean gas;
delivering the energized preclean gas to the substrate;
purging the processing chamber; and
depositing one or more silicon oxide/silicon containing stacks on a substrate in the presence of a vacuum, wherein depositing a silicon oxide/silicon-containing stack comprises:
energizing a first process gas into a first plasma;
depositing a first material layer on the substrate from the first plasma;
energizing a second process gas into a second plasma;
depositing a layer of a second material on the substrate from the second plasma; and
repeating the above steps until a predetermined number of the first material layers and the second material layers have been deposited on the substrate, wherein the first material layer and the second material layer are either a silicon oxide layer or an amorphous silicon layer and wherein the second material layer is different from the first material layer.

2. The method of claim 1, wherein the substrate comprises a carbon-containing residue and the preclean gas is an oxygen-containing gas.

3. The method of claim 1, wherein the substrate comprises an oxygen-containing residue and the preclean gas is a hydrogen-containing gas.

4. The method of claim 1, wherein the preclean gas is an inert gas.

5. The method of claim 1, further comprising:
plasma purging the processing chamber to expose a surface of the first material layer, creating first gas contaminants;
gas purging the processing chamber to remove the first gas contaminants;
plasma purging the processing chamber to expose a surface of the second material layer, creating second gas contaminants; and
gas purging the processing chamber to remove the second gas contaminants.

6. The method of claim 1, wherein the first material layer and the second material layer are deposited at a temperature between about 500 degrees Celsius and about 650 degrees Celsius.

7. The method of claim 1, wherein the substrate comprises an inner zone and an outer zone which circumscribes the inner zone, and wherein the temperature of the outer zone is between 5 degrees Celsius and about 20 degrees Celsius higher than the temperature of the inner zone.

8. The method of claim 1, wherein the first material layer and the second material layer are sequentially annealed at a temperature between about 500 degrees Celsius and about 650 degrees Celsius.

9. The method of claim 1, wherein the first material layer has a first thickness and the second material layer has a second thickness, and wherein the first thickness is less than the second thickness.

10. The method of claim 1, wherein the silicon oxide layer has a tensile stress.

11. The method of claim 1, wherein the amorphous silicon layer comprises boron.

12. A method of forming a stack comprising:
energizing a first process gas into a first plasma;
depositing a first material layer on the substrate from the first plasma, the layer of the first material having a first thickness;
plasma purging the PECVD chamber to expose a surface of the first material layer, creating first gas contaminants;
gas purging the PECVD chamber to remove the first gas contaminants;
energizing a second process gas into a second plasma;
depositing a second material layer on the first material layer from the second plasma, the second material layer having a second thickness;
plasma purging the PECVD chamber to expose a surface of the second material layer, creating second gas contaminants;
gas purging the PECVD chamber to remove the second gas contaminants; and
repeating the above steps until a predetermined number of the first material layers and the second material layers have been deposited on the substrate, wherein, during at least one of the above steps, at least a portion of the chamber, the substrate support or combinations thereof is maintained at a temperature of between about 500 degrees Celsius and about 650 degrees Celsius, wherein the first material layer and the second material layer are either a silicon oxide layer or an amorphous silicon layer and wherein the second material layer is different from the first material layer.

13. The method of claim 12, wherein the substrate is maintained at a temperature between 500 degrees Celsius and 650 degrees Celsius during the deposition of the first material layer and the deposition of the second material layer.

14. The method of claim 12, wherein the substrate comprises an inner zone and an outer zone which circumscribes the inner zone, and wherein the temperature of the outer zone is between 5 degrees Celsius and about 20 degrees Celsius higher than the temperature of the inner zone.

15. The method of claim 12, wherein the first material layer and the second material layer are sequentially annealed at a temperature between about 500 degrees Celsius and about 650 degrees Celsius.

16. The method of claim 15, wherein the anneal has a controlled ramp rate.

17. The method of claim 12, wherein the first material layer has a first thickness and the second material layer has a second thickness, and wherein the first thickness is less than the second thickness.

18. The method of claim 12, wherein the silicon oxide layer has a tensile stress.

19. The method of claim 12, wherein the substrate receives a silane soak prior to deposition of the first material layer.

20. A method of forming a stack comprising:
energizing a first process gas into a first plasma;
depositing a first material layer on the substrate from the first plasma, the layer of the first material having a first thickness, the substrate being maintained at a temperature between 500 degrees Celsius and 650 degrees Celsius;
plasma purging the PECVD chamber to expose a surface of the first material layer, creating first gas contaminants;
gas purging the PECVD chamber to remove the first gas contaminants;
energizing a second process gas into a second plasma;
depositing a second material layer on the first material layer from the second plasma, the second material layer having a second thickness, the substrate being maintained at a temperature between 500 degrees Celsius and 650 degrees Celsius, wherein the first material layer has a first thickness and the second material layer has a second thickness, and wherein the first thickness is less than the second thickness;
plasma purging the PECVD chamber to expose a surface of the second material layer, creating second gas contaminants;
gas purging the PECVD chamber to remove the second gas contaminants; and
repeating the above steps until a predetermined number of the first material layers and the second material layers have been deposited on the substrate, wherein, during at least one of the above steps, at least a portion of the chamber, the substrate support or combinations thereof is maintained at a temperature of between about 500 degrees Celsius and about 650 degrees Celsius, wherein the first material layer and the second material layer are either a silicon oxide layer or an amorphous silicon layer and wherein the second material layer is different from the first material layer.
